(19) United States
(12) Patent Application Publication
(10) Pub. No.: US 2021/0183631 A1
(43) Pub. Date: Jun. 17, 2021

(54) PLASMA PROCESSING APPARATUS AND PLASMA PROCESSING METHOD

(71) Applicant: Tokyo Electron Limited, Tokyo (JP)

(72) Inventors: Koji Yamagishi, Kurokawa-gun (JP); Daisuke Shirasawa, Kurokawa-gun (JP)

(21) Appl. No.: 17/122,169

(22) Filed: Dec. 15, 2020

(30) Foreign Application Priority Data
Dec. 17, 2019 (JP) 2019-227677

(51) Int. Cl. H01J 37/32

(52) U.S. Cl. CPC H01J 37/32862; H01J 37/32082; H01J 37/32715; H01J 2237/334; H01J 37/32568; H01J 2237/20235; H01J 37/32834

(57) ABSTRACT

A chamber is configured to process a substrate by using a plasma. A heater is disposed in a region within the chamber which is not exposed to the plasma and a radio frequency power supplied for plasma formation. A heater power supply is configured to supply a pulsed power to the heater.

### CROSS-REFERENCE TO RELATED APPLICATION

This application claims the benefit of Japanese Patent Application No. 2019-227677 filed on Dec. 17, 2019, the entire disclosures of which are incorporated herein by reference.

### TECHNICAL FIELD

The various aspects and embodiments described herein pertain generally to a plasma processing apparatus and a plasma processing method.

### BACKGROUND

Patent Document 1 describes a technique of removing a deposit on a non-plasma surface in a space at an outside of an insulated plasma processing chamber by generating plasma from a fluorocarbon gas and supplying the generated plasma into the space at the outside of the plasma processing chamber.

Patent Document 1: Japanese Patent Laid-open Publication No. 2018-195817

### SUMMARY

In an exemplary embodiment, a plasma processing apparatus includes a chamber, a heater and a heater power supply. The chamber is configured to process a substrate by using a plasma. The heater is disposed in a region within the chamber which is not exposed to the plasma and a radio frequency power. The heater power supply is configured to supply a pulsed power to the heater.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram schematically illustrating an example of a cross section of a plasma processing apparatus according to an exemplary embodiment;

FIG. 2 is a diagram illustrating an example of a layout of a heater according to the exemplary embodiment;

FIG. 3 is a diagram illustrating an example of a temperature variation of the heater according to the exemplary embodiment;

FIG. 4 is a diagram illustrating an example of a pulsed power to be supplied to the heater according to the exemplary embodiment;

FIG. 5 is a diagram illustrating an example of heating by the heater according to the exemplary embodiment;

FIG. 6 is a diagram illustrating an example of temperature variations of a front surface and a rear surface of a member according to the exemplary embodiment;

FIG. 7 is a diagram illustrating an example of a test object according to the exemplary embodiment;

FIG. 8 is a diagram illustrating an outline of an experiment according to the exemplary embodiment;

FIG. 9 is a diagram illustrating a schematic layout of the heater and the test object according to the exemplary embodiment;

FIG. 10 is a diagram illustrating an experimental result according to the exemplary embodiment; and

FIG. 11 is a diagram schematically illustrating an example of a cross section of a plasma processing apparatus according to another exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of a plasma processing apparatus and a plasma processing method according to the present disclosure will be described in detail with reference to the accompanying drawings. Further, it should be noted that the plasma processing apparatus and the plasma processing method according to the present disclosure are not limited to the exemplary embodiments.

A by-product is generated when a plasma processing is performed, and the generated by-product is scattered around within a chamber, ending up with being attached to the chamber. Thus, there is known a technique of cleaning the by-product by using plasma, as described in Patent Document 1, for example. In a region within the chamber which is not exposed to the plasma and a radio frequency (radio frequency) power applied to form the plasma, however, the by-product is difficult to remove even if the plasma is used. As a result, the by-product may be easily deposited in that region. Though the deposited by-product needs to be removed regularly with a scraper or the like, there arises a risk that a harmful gas or the like may be generated.

In this regard, there has been a demand for a technique capable of suppressing deposition of the by-product in the region within the chamber which is not exposed to the plasma and the radio frequency power.

### First Exemplary Embodiment

<Configuration of Plasma Processing Apparatus>

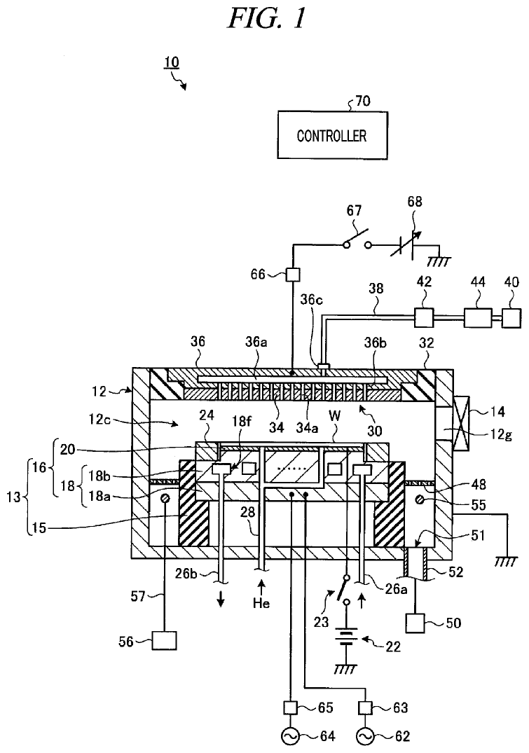

An example of a plasma processing apparatus according to a first exemplary embodiment will be described. The present exemplary embodiment will be explained for an example where the plasma processing apparatus etches a substrate by using a plasma as a plasma processing. Here, the substrate is a wafer. FIG. 1 is a diagram schematically illustrating an example of a cross section of a plasma processing apparatus 10 according to the exemplary embodiment. The plasma processing apparatus 10 shown in FIG. 1 is a capacitively coupled plasma processing apparatus.

The plasma processing apparatus 10 is equipped with a chamber 12. The chamber 12 has a substantially cylindrical shape, and is made of, by way of non-limiting example, aluminum and hermetically sealed. An internal space of the chamber 12 is configured as a processing space 12c in which a plasma processing is performed. A film having plasma-resistance is formed on an inner wall surface of the chamber 12. This film may be an alumite film or an yttrium oxide film. The chamber 12 is grounded. An opening 12g is formed in a sidewall of the chamber 12. When a wafer W is carried into the processing space 12c from an outside of the chamber 12 or when the wafer W is carried out from the processing space 12c to the outside of the chamber 12, the wafer W passes through the opening 12g. A gate valve 14 is provided at the sidewall of the chamber 12 to open or close the opening 12g.

Within the chamber 12, a substrate support 13 configured to support the wafer W is provided near a center of the chamber 12. The substrate support 13 includes a supporting member 15 and a stage 16. The supporting member 15 has a substantially cylindrical shape and is provided on a bottom of the chamber 12. The supporting member 15 is made of, by way of non-limiting example, an insulating material. Within the chamber 12, the supporting member 15 is extended upwards from the bottom of the chamber 12. The stage 16 is provided within the processing space 12c. The stage 16 is supported by the supporting member 15.

The stage 16 is configured to hold the wafer W placed thereon. The stage 16 includes a lower electrode 18 and an electrostatic chuck 20. The lower electrode 18 includes a first plate 18a and a second plate 18b. Each of the first plate 18a and the second plate 18b is made of a metal such as, but not limited to, aluminum, and has a substantially disk shape. The second plate 18b is provided on the first plate 18a and electrically connected with the first plate 18a.

The electrostatic chuck 20 is provided on the second plate 18b. The electrostatic chuck 20 includes an insulating layer and a film-shaped electrode embedded in the insulating layer. The electrode of the electrostatic chuck 20 is electrically connected with a DC power supply 22 via a switch 23. A DC voltage from the DC power supply 22 is applied to the electrode of the electrostatic chuck 20. If the DC voltage is applied to the electrode of the electrostatic chuck 20, an electrostatic attracting force is generated in the electrostatic chuck 20 and attracts the wafer W toward the electrostatic chuck 20, thus allowing the wafer W to be held on the electrostatic chuck 20. Further, a heater may be embedded within the electrostatic chuck 20, and this heater may be connected to a heater power supply provided at an outside of the chamber 12.

A focus ring 24 is provided on a peripheral portion of the second plate 18b. The focus ring 24 is a substantially annular plate. The focus ring 24 is disposed to surround an edge of the wafer W and the electrostatic chuck 20. The focus ring 24 is configured to improve etching uniformity. The focus ring 24 may be formed of such a material as, but not limited to, silicon or quartz.

A path 18f is formed within the second plate 18b. A temperature control fluid is supplied via a pipeline 26a into the path 18f from a chiller unit provided at an outside of the chamber 12. The temperature control fluid supplied into the path 18f is returned back into the chiller unit via a pipeline 26b. That is, the temperature control fluid is circulated between the path 18f and the chiller unit. By controlling a temperature of this temperature control fluid, a temperature of the stage 16 (or the electrostatic chuck 20) and a temperature of the wafer W are adjusted. As an example of the temperature control fluid, Galden (registered trademark) may be used.

The plasma processing apparatus 10 is provided with a gas supply line 28. The gas supply line 28 supplies a heat transfer gas such as, but not limited to, a He gas from a heat transfer gas supply device into a gap between a top surface of the electrostatic chuck 20 and a rear surface of the wafer W.

The plasma processing apparatus 10 is further equipped with a shower head 30. The shower head 30 is disposed above the stage 16. The shower head 30 is supported at an upper portion of the chamber 12 with an insulating member 32 therebetween. The shower head 30 may include an electrode plate 34 and a supporting body 36. A bottom surface of the electrode plate 34 is in direct contact with a processing space 12c. The electrode plate 34 is provided with a multiple number of gas discharge holes 34a. This electrode plate 34 may be made of a material such as, but not limited to, silicon or silicon oxide.

The supporting body 36 is configured to support the electrode plate 34 in a detachable manner, and is made of a conductive material such as aluminum. A gas diffusion space 36a is provided within the supporting body 36. A multiple number of gas through holes 36b extend downwards from the gas diffusion space 36a to communicate with the gas discharge holes 34a. The supporting body 36 is provided with a gas inlet opening 36c through which a gas is introduced into the gas diffusion space 36a. A gas supply line 38 is connected to the gas inlet opening 36c.

The gas supply line 38 is connected to a gas source group 40 via a valve group 42 and a flow rate controller group 44. The gas source group 40 includes a plurality of gas sources for various kinds of gases for use in plasma etching. The valve group 42 includes a plurality of valves, and the flow rate controller group 44 includes a plurality of flow rate controllers such as mass flow controllers or pressure control type flow rate controllers. Each of the gas sources belonging to the gas source group 40 is connected to the gas supply line 38 via a corresponding valve belonging to the valve group 42 and a corresponding flow rate controller belonging to the flow rate controller group 44. The gas source group 40 supplies the various kinds of gases for the plasma etching into the gas diffusion space 36a of the supporting body 36 through the gas supply line 38. The gases introduced into the gas diffusion space 36a are supplied from the gas diffusion space 36a into the chamber 12 through the gas through holes 36b and the gas discharge holes 34a while being distributed in a shower shape.

A first radio frequency power supply 62 is connected to the lower electrode 18 via a matching device 63. Further, a second radio frequency power supply 64 is connected to the lower electrode 18 via a matching device 65. The first radio frequency power supply 62 is a power source configured to generate a radio frequency power for plasma formation. In the plasma processing, the first radio frequency power supply 62 supplies the radio frequency power having a preset frequency ranging from 27 MHz to 100 MHZ, e.g., 40 MHz to the lower electrode 18 of the stage 16. The second radio frequency power supply 64 is a power source configured to generate a radio frequency power for ion attraction (bias). The second radio frequency power supply 64 supplies the radio frequency power having a predetermined frequency lower than the first radio frequency power supply 62 ranging from 400 kHz to 13.56 MHz, e.g., 3 MHz to the lower electrode 18 of the stage 16. In this way, the stage 16 is configured to be capable of applying the dual radio frequency powers having the different frequencies from the first radio frequency power supply 62 and the second radio frequency power supply 64. The shower head 30 and the stage 16 serve as a pair of electrodes (an upper electrode and a lower electrode).

The supporting body 36 of the shower head 30 is connected to a variable DC power supply 68 via a low pass filter (LPF) 66. The variable DC power supply 68 is configured to turn on/off a power feed by an on/off switch 67. A current/voltage of the variable DC power supply 68 and an on/off operation of the on/off switch 67 are controlled by a controller 70 to be described later. Further, when plasma is formed in the processing space as the radio frequency powers from the first radio frequency power supply 62 and the second radio frequency power supply 64 are applied to the stage 16, the on/off switch 67 is turned on by the controller 70 when necessary, and a preset DC voltage is applied to the supporting body 36.

An exhaust port 51 is formed at a bottom of the chamber 12 next to the substrate support 13. The exhaust port 51 is connected with an exhaust device 50 via an exhaust line 52. The exhaust device 50 includes a pressure controller such as a pressure control valve and a vacuum pump such as a turbo molecular pump. The exhaust device 50 is capable of decompressing the chamber 12 to a required pressure level by evacuating the chamber 12 through the exhaust port 51 and the exhaust line 52.

The chamber 12 is provided with a baffle plate 48 at an upstream of the exhaust port 51 with regard to a flow of an exhaust gas toward the exhaust port 51. The baffle plate 48 is disposed between the substrate support 13 and an inner side surface of the chamber 12, surrounding the substrate support 13. The baffle plate 48 is, for example, a plate-shaped member and may be formed by coating a surface of an aluminum base member with ceramics such as Y₂O₃. The baffle plate 48 is made of a member having multiple number of slits, a mesh member, or a member having a multiple number of punching holes, so the exhaust gas can pass through the baffle plate 48. An internal space of the chamber 12 is partitioned by the baffle plate 48 into the processing space 12c in which the wafer W is processed by using the plasma; and an exhaust space connected with an exhaust system such as the exhaust line 52 and the exhaust device 50 configured to evacuate the chamber 12.

A heater 55 is provided in a region within the chamber 12 which is not exposed to the plasma and the radio frequency powers. As an example, the heater 55 is disposed in the exhaust space. The heater 55 may be, by way of non-limiting example, an infrared heater such as a carbon wire heater. The heater 55 is disposed to surround the substrate support 13 while being spaced apart from the inner side surface of the chamber 12, the bottom of the chamber 12, the substrate support 13 and the baffle plate 48. That is, the heater 55 is provided along a side surface of the substrate support 13 while being distanced apart from the chamber 12, the substrate support 13 and the baffle plate 48 lest the heater 55 should be in contact with the chamber 12, the substrate support 13 and the baffle plate 48. The heater 55 is connected to a heater power supply 56 via a wiring 57. The heater 55 generates heat by a power supplied from the heater power supply 56, and radiates infrared rays and heats members nearby. The heater power supply 56 supplies the power to the heater 55 in a pulse shape under the control of the controller 70 to be described below. Furthermore, the heater power supply 56 may be a DC power supply or a radio frequency power supply.

The plasma processing apparatus 10 is further equipped with the controller 70. The controller 70 may be, by way of example, a computer including a processor, a storage, an input device, a display device, and so forth. The controller 70 controls the individual components of the plasma processing apparatus 10. In the controller 70, a command or the like may be inputted by an operator through the input device to manage the plasma processing apparatus 10. Further, in the controller 70, an operational status of the plasma processing apparatus 10 can be visually displayed by the display device. Further, control programs for controlling various processings to be performed in the plasma processing apparatus 10 by the processor and recipe data are stored in the storage of the controller 70. As the processor of the controller 70 executes the control programs and controls the individual components of the plasma processing apparatus 10 according to the recipe data, a required processing is performed in the plasma processing apparatus 10.

As mentioned above, in the plasma processing, a by-product is generated as the plasma processing is performed, and the generated by-product is scattered around within the chamber 12 and attached thereto. There is known a technique of cleaning this by-product by using plasma, as described in Patent Document 1, for example. In the cleaning using the plasma, however, it is difficult to remove the by-product from a region within the chamber 12 which is not exposed to the plasma and the radio frequency powers. By way of example, since the plasma and the radio frequency powers are blocked by the baffle plate 48, the plasma and the radio frequency powers may not reach a space under the baffle plate 48 within the chamber 12. Therefore, the by-product may be easily deposited under the baffle plate 48 within the chamber 12.

As a resolution, in the plasma processing apparatus 10, the heater 55 is placed in the region which is not exposed to the plasma and the radio frequency powers. For example, in the present exemplary embodiment, the heater 55 is disposed in the space under the baffle plate 48 within the chamber 12.

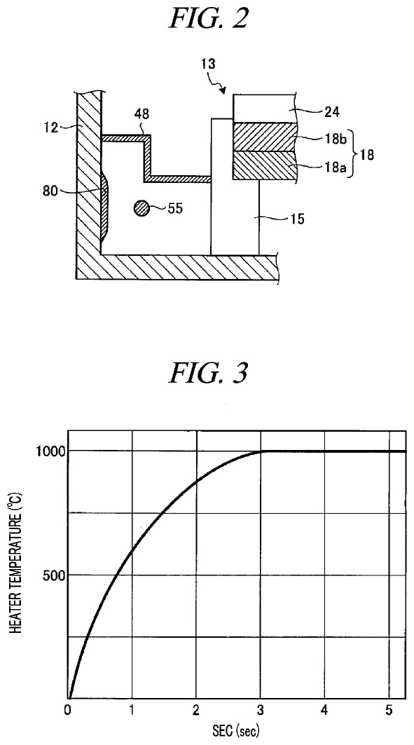

FIG. 2 is a diagram illustrating a layout of the heater 55 according to the exemplary embodiment. FIG. 2 shows the space under the baffle plate 48 within the chamber 12 and the vicinity thereof. In the space under the baffle plate 48 within the chamber 12, the by-product may be easily deposited on a region 80 on the inner side surface of the chamber 12. On this ground, the heater 55 is placed at a preset distance from the region 80 within the chamber 12 where the by-product may be easily deposited.

The heater 55 generates heat when the power is supplied from the heater power supply 56. FIG. 3 is a diagram illustrating an example of a temperature variation of the heater 55 according to the exemplary embodiment. FIG. 3 shows the temperature variation after the power is supplied to the carbon wire heater used as the heater 55. As can be seen from FIG. 3, if the power is supplied, a temperature of the carbon wire heater increases rapidly to 1000° C. in about 3 seconds.

If the heater power supply 56 supplies the power to the heater 55, the heater 55 generates the heat, and the region 80 on the inner side surface of the chamber 12 is heated by the heat from the heater 55. Accordingly, adhesion of the by-product is suppressed or the by-product is removed.

If the power is continuously supplied to the heater 55 from the heater power supply 56 to suppress adhesion of the by-product or remove the by-product, the heat in the region 80 on the inner side surface of the chamber 12 is transferred to an outer surface of the chamber 12, resulting in an increase of a temperature of the outer surface of the chamber 12. For example, an outer surface of the chamber 12 corresponding to the region 80 may be heated to a high temperature. If the outer surface of the chamber 12 is excessively heated, a countermeasure such as providing a heat insulator on the outer surface of the chamber 12 or the like is required for the sake of safety of the apparatus. Thus, it is desirable to maintain the outer surface of the chamber 12 at a temperature equal to or less than a preset tolerance temperature (e.g., 50° C.) which is regarded as being safe.

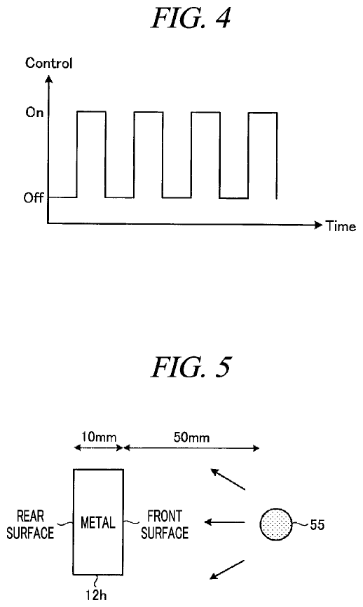

For the purpose, the heater power supply 56 supplies the pulsed power to the heater 55. FIG. 4 is a diagram illustrating an example of the pulsed power which is supplied to the heater according to the exemplary embodiment. The controller 70 turns on/off the supply of the power by the heater power supply 56, thus allowing the pulsed power to be supplied to the heater 55.

By disposing the heater 55 within the chamber 12, a heating time can be shortened, and an inner surface of the chamber 12 can be heated efficiently. Further, by repeating heating/cooling by the heater 55 by way of supplying the pulsed power to the heater 55, a temperature rise of the outer surface of the chamber 12 can be suppressed. A frequency of the pulsed power may be set to be equal to or lower than, e.g., 0.05 Hz.

FIG. 5 is a diagram showing an example of heating by the heater 55 according to the exemplary embodiment. FIG. 5 illustrates a flat plate-shaped member 12h as a copy of the sidewall of the chamber 12. The member 12h is made of the same metal (for example, aluminum) as the chamber 12 and has a thickness of 10 mm. A surface of the member 12h at a right-hand side of FIG. 5 is referred to as a front surface, and a surface at a left-hand side of FIG. 5 is referred to as a rear surface. The heater 55 is placed at a position 50 mm apart from the front surface of the member 12h. In this configuration, the front surface of the member 12h corresponds to an inner wall surface of the chamber 12. The rear surface of the member 12h corresponds to an outer wall surface of the chamber 12.

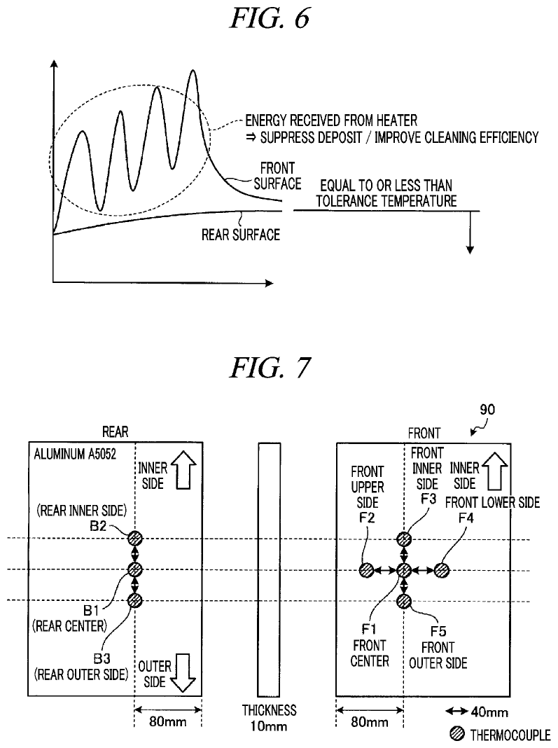

When the pulsed power is supplied to this heater 55, since the heat from the heater 55 is directly irradiated to the front surface of the member 12h, a temperature of the front surface of the member 12h varies in response to a turning-on/off of the power supply. Meanwhile, since a temperature of the rear surface of the member 12h is changed by the heat transferred from the front surface thereof, a temperature variation of this rear surface is not as big as the temperature variation of the front surface. FIG. 6 is a diagram illustrating an example of the temperature variations of the front surface and the rear surface of the member 12h according to the exemplary embodiment. In a power-on period during which the power supply is on, the temperature of the front surface of the member 12h increases rapidly due to the heat radiated from the heater 55. In a power-off period in which the power supply is off, on the other hand, the temperature of the front surface of the member 12h decreases rapidly as the heat is diffused within the member 12h. Meanwhile, since the heat radiation to the front surface of the member 12h from the heater 55 is stopped before the temperature of the rear surface of the member 12h increases rapidly due to the heat transferred from the front surface, the temperature of the rear surface of the member 12h no longer increases after being raised gently.

Thus, by adjusting the power-on period and the power-off period appropriately, the temperature of the front surface of the member 12h can be temporarily raised to a temperature at which the by-product is removed in the power-on period, while the temperature of the rear surface of the member 12h is maintained at a temperature equal to or lower than the tolerance temperature. The front surface of the member 12h corresponds to the inner wall surface of the chamber 12. The rear surface of the member 12h corresponds to the outer wall surface of the chamber 12. Thus, it is possible to temporarily increase the temperature of the inner wall surface of the chamber 12 up to the temperature at which the by-product is removed in the power-on period, while maintaining the temperature of the outer wall surface of the chamber 12 at the temperature equal to or lower than the tolerance temperature.

The controller 70 controls the heater power supply 56 to supply the pulsed power to the heater 55 while adjusting the power-on period and the power-off period appropriately. By way of example, a proper cycle of the power-on period and the power-off period is calculated through an experiment or the like. The controller 70 controls the heater power supply 56 to supply the pulsed power to the heater 55 with the calculated cycle. The controller 70 controls the heater power supply 56 to repeat an operation of turning-off the power supply after keeping on the power supply until the region 80 on the inner side surface of the chamber 12 is heated by the heat from the heater 55 to the temperature at which the by-product attached to the region 80 in the plasma processing volatilizes. By way of example, the controller 70 controls the heater power supply 56 to repeat the turning-on/off of the power supply such that, in the power-on period, the region 80 reaches the temperature at which the by-product volatilizes and the outer surface of the chamber 12 corresponding to the region 80 becomes equal to or lower than the tolerance temperature. For instance, when the by-product generated by the plasma processing is a titanium-based by-product, the controller 70 controls the heater power supply 56 to increase the temperature of the region 80 on the inner side surface of the chamber 12 to 80° C. to 100° C. temporarily in the power-on period.

Accordingly, the plasma processing apparatus 10 is capable of suppressing deposition of the by-product onto the region 80 on the inner side surface of the chamber 12. Further, the plasma processing apparatus 10 is also capable of suppressing the temperature of the outer surface of the chamber 12 corresponding to the region 80 to the tolerance temperature or less.

Moreover, though the present exemplary embodiment has been described for the example where deposition of the by-product on the region 80 on the inner side surface of the chamber 12 is suppressed, the present exemplary embodiment is not limited thereto. The heater 55 can be placed at any region within the chamber 12 where the deposition of the by-product needs to be suppressed. By disposing the heater 55 at a position corresponding to the region within the chamber 12 which is not exposed to the plasma and the radio frequency powers and supplying the pulsed power to the heater 55 from the heater power supply 56, the by-product can be suppressed from being deposited on the region within the chamber 12 which is not exposed to the plasma and the radio frequency powers.

Further, the inside of the chamber may be cleaned by using plasma. As an example, in the cleaning, a plasma processing is performed in the state that the wafer W is not placed in the chamber 12, or in the state that a dummy wafer is placed therein. In this cleaning, the controller 70 may control the heater power supply 56 to supply the pulsed power to the heater 55, thus accelerating removal of the by-product. For example, when the wafer W is plasma-processed, the controller 70 controls the heater power supply 56 to supply the power until the region not exposed to the plasma and the radio frequency powers reaches a first temperature in the power-on period during which the heater power supply 56 is on. For example, the first temperature is a temperature at which adhesion of the by-product is suppressed. Further, when the inside of the chamber 12 is cleaned with the plasma in the state that the wafer W is not placed within the chamber 12 or in the state that the dummy wafer is placed therein, the controller 70 controls the heater power supply 56 to supply the power until the region not exposed to the plasma and the radio frequency powers reaches a second temperature in the power-on period during which the heater power supply 56 is on. As an example, the second temperature is a temperature at which the removal of the by-product is accelerated. The second temperature may be set to be higher than the first temperature. By way of example, if the by-product generated by the plasma processing is the titanium-based by-product, the temperature of the region 80 on the inner side surface of the chamber 12 is increased up to 80° C. to 100° C. temporarily in the power-on period during which the heater power supply 56 is on, when the wafer W is plasma-processed. Accordingly, the titanium-based by-product generated when the plasma processing is performed can be suppressed from being attached to the region 80. Meanwhile, when the cleaning is performed, the temperature of the region 80 on the inner side surface of the chamber 12 is temporarily increased up to 100° C. to 120° C. in the power-on period during which the heater power supply 56 is on. As a result, the removal of the titanium-based by-product attached to the region 80 can be accelerated.

Now, a specific example will be explained. In the following, an experiment where a temperature is measured by using a test object having a flat plate shape as a copy of the sidewall of the chamber 12 will be explained. FIG. 7 is a diagram illustrating an example of the test object according to the exemplary embodiment. FIG. 7 shows a structure of a flat plate-shaped test object 90. An aluminum (A5052) flat plate having a size of 360 mm×200 mm and a thickness of 10 mm is used as the test object 90. An upper side and a lower side of the test object 90 in FIG. 7 are defined as an inner side and an outer side, and a left side and a right side of the test object 90 in FIG. 7 are defined as an upper side and a lower side. The test object 90 is provided with thermocouples for measuring a temperature respectively provided at five front-surface positions of the test object 90: a position F1 (front center) near a center of a front surface thereof and positions F2 (front upper side), F3 (front inner side), F4 (front lower side) and F5 (front outer side) 40 mm apart from the position F1 to the upper side, the inner side, the lower side and the outer side, respectively. Further, the test object 90 is also provided with thermocouples for measuring a temperature which are respectively provided at a rear-surface position B1 (rear center) corresponding to the front-surface position F1, a rear-surface position B2 (rear inner side) corresponding to the front-surface position F3, and a rear-surface position B3 (rear outer side) corresponding to the front-surface position F5. The positions B2 and B3 are located 40 mm apart from the position B1 near a center of a rear surface to the inner side and the outer side, respectively.

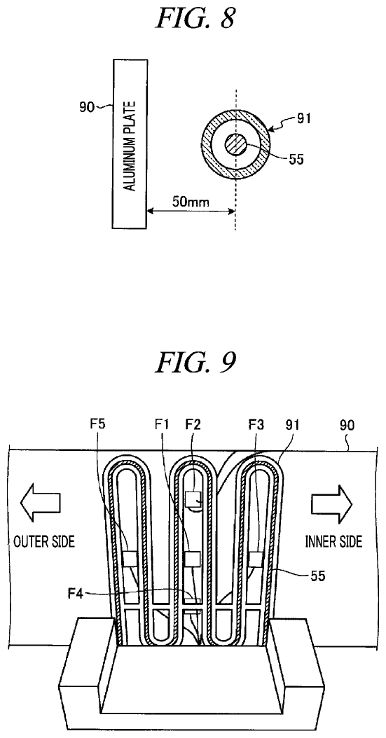

FIG. 8 is a diagram for describing an outline of the experiment according to the exemplary embodiment. In the experiment, heating is performed by the heater 55 placed at a position 55 mm away from the front surface of this test object 90. A carbon wire heater is used as the heater 55. The heater 55 is disposed through a glass pipe 91 to correspond to regions on the front surface of the test object 90 where the thermocouples are provided. FIG. 9 is a diagram showing a schematic layout of the heater 55 and the test object 90 according to the exemplary embodiment. The heater 55 is disposed through the transparent zigzag glass pipe 91 to face the regions of the positions F1 to F5 while being distanced 50 mm apart from the front surface of the test object 90.

In the experiment, a power having a current value of 20 A is supplied to the heater 55 when the power is on, and a current value is set to be OA when the power is off. In this way, the on/off powers are supplied in a pulse shape.

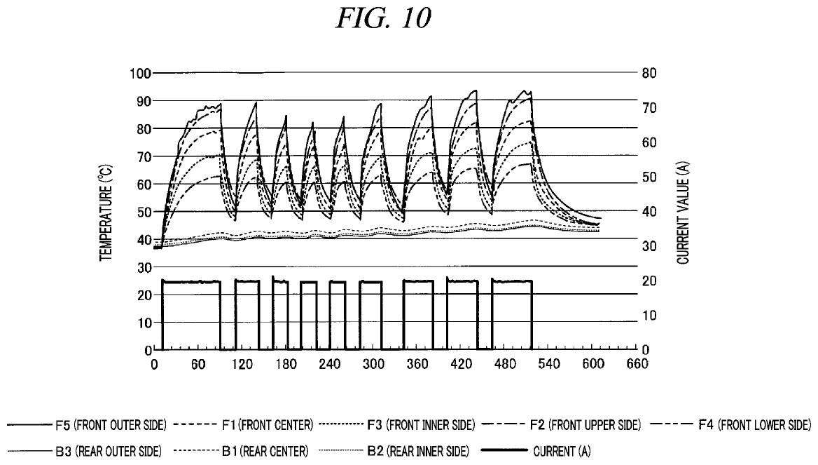

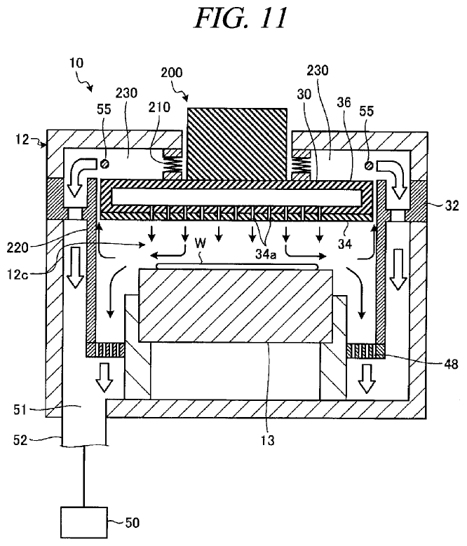

FIG. 10 is a diagram showing an experimental result according to the exemplary embodiment. A variation of the current value supplied to the heater 55 is shown in a lower portion of FIG. 10. Further, measurement results at the front-surface five positions F1 to F5 by the thermocouples placed on the front surface of the test object 90, and measurement results at the rear-surface three positions B1 to B3 by the thermocouples placed on the rear surface of the test object 90 are shown in FIG. 10.

As shown in FIG. 10, a temperature of the front surface of the test object 90 can be varied in response to the turning on/off of the power supply, and the front surface of the test object 90 can be temporarily increased in a power-on period up to a temperature where a by-product is removed. By way of example, the temperatures at the front-surface positions F1 (front center), F2 (front upper side) and F5 (front outer side) are temporarily increased in the power-on period up to 80° C. or higher at which the titanium-based by-product is removed. Meanwhile, the temperatures at the rear surface positions (rear center, rear outer side, and rear inner side) are maintained equal to or lower than 50° C.

Thus, in the plasma processing apparatus 10, by placing the heater 55 within the chamber 12 appropriately and supplying the pulsed power to the heater 55, deposition of the by-product within the chamber 12 can be suppressed.

As stated above, the plasma processing apparatus 10 according to the exemplary embodiment is equipped with the chamber 12, the heater 55, and the heater power supply 56. The chamber 12 is configured to process the wafer W by using the plasma. The heater 55 is disposed to corresponding to the region within the chamber 12 which is not exposed to the plasma and the radio frequency powers. The heater power supply 56 is configured to supply the pulsed power to the heater 55. With this configuration, the plasma processing apparatus 10 is capable of suppressing deposition of the by-product in the region within the chamber 12 which is not exposed to the plasma and the radio frequency powers.

Further, the plasma processing apparatus 10 is further equipped with the exhaust port 51 and the baffle plate 48. The chamber 12 is evacuated through the exhaust port 51. The baffle plate 48 is disposed at the upstream of the exhaust port 51 with regard to the flow of the exhaust gas within the chamber 12 toward the exhaust port 51. The heater 55 is provided at the downstream of the baffle plate 48 with regard to the flow of the exhaust gas toward the exhaust port 51. Accordingly, the plasma processing apparatus 10 is capable of suppressing the by-product from being deposited in the region at the downstream of the baffle plate 48 where the by-product may be easily deposited.

Furthermore, the plasma processing apparatus 10 is further equipped with the substrate support 13. The substrate support 13 is disposed within the chamber 12 and supports the wafer W. The baffle plate 48 is disposed to surround the substrate support 13 between the substrate support 13 and the inner side surface of the chamber 12. The heater 55 is placed between the baffle plate 48 and the exhaust port 51, surrounding the substrate support 13. With this configuration, the plasma processing apparatus 10 according to the exemplary embodiment is capable of suppressing deposition of the by-product in the region around the substrate support 13 under the baffle plate 48.

Moreover, the heater power supply 56 repeats the operation of turning-off the power supply after keeping on the power supply until the region not exposed to the plasma and the radio frequency powers is heated by the heat from the heater 55 to the temperature at which the by-product volatilizes. Accordingly, in the plasma processing apparatus 10 according to the present exemplary embodiment, deposition of the by-product in the region not exposed to the plasma and the radio frequency powers can be suppressed.

In addition, the heater power supply 56 repeats the turning-on/off of the power supply such that, in the power-on period, the temperature of the region which is not exposed to the plasma and the radio frequency powers reaches the temperature at which the by-product volatilizes while the temperature of the outer surface of the chamber 12 corresponding to the region which is not exposed to the plasma and the radio frequency powers becomes equal to or lower than the tolerance temperature. Accordingly, the plasma processing apparatus 10 according to the exemplary embodiment is capable of suppressing deposition of the by-product in the region which is not exposed to the plasma and the radio frequency powers. Further, the plasma processing apparatus 10 according to the exemplary embodiment is capable of maintaining the outer surface of the chamber 12 equal to or lower than the tolerance temperature.

The exemplary embodiments disclosed so far are illustrative in all aspects and not limited thereto. In fact, the above exemplary embodiments can be embodied in various forms. Further, the above-described exemplary embodiments may be omitted, substituted, or changed in various forms without departing from the scope of the appended claims

By way of example, the above-exemplary embodiment has been described for the example where the cycle of the power-on period and the power-off period for the power supplied to the heater 55 from the heater power supply 56 is appropriately adjusted and set in advance. However, the exemplary embodiment may not be limited thereto. A temperature may be measured by using a temperature sensor, and the power-on period and the power-off period may be controlled based on the measured temperature. By way of example, the heater 55 is placed to correspond to a target region within the chamber 12 where deposition of the by-product needs to be suppressed. Further, the temperature sensor is provided at the target region within the chamber 12 and an outer surface of the chamber 12 corresponding to the target region. The heater power supply 56 may repeat, in the pulse shape, turning-off the power supply after keeping on supplying the power to the heater 55 from the heater power supply 56 until the temperature measured by the temperature sensor provided in the target region reaches the temperature at which the by-product volatilizes. Further, the heater power supply 56 may lengthen the power-off period as the temperature measured by the temperature sensor provided at the outer surface of the chamber 12 approaches the tolerance temperature.

Additionally, the above exemplary embodiment has been described for the example where the plasma processing apparatus 10 is the capacitively coupled plasma processing apparatus. However, the exemplary embodiment is not limited thereto and applicable to any of various kinds of plasma processing apparatuses. By way of example, the plasma processing apparatus 10 may be any of various kinds of plasma processing apparatuses such as an inductively coupled plasma processing apparatus, a plasma processing apparatus configured to excite a gas by a surface wave such as a microwave, and so forth.

Further, in the above-described exemplary embodiment, the first radio frequency power supply 62 and the second radio frequency power supply 64 are connected to the lower electrode 18. However, a configuration of the plasma source is not limited thereto. By way of example, the first radio frequency power supply 62 for plasma formation may be connected to the shower head 30. Further, the second radio frequency power supply 64 for ion attraction (bias) may not be connected to the lower electrode 18.

In addition, in the above-described exemplary embodiment, an inter-electrode distance between the shower head 30 serving as an upper electrode and the stage 16 serving as a lower electrode is fixed. However, the exemplary embodiment is not limited thereto. In a parallel plate type plasma processing apparatus, the inter-electrode distance between the upper electrode and the lower electrode affects a plasma processing characteristic of a substrate. Thus, the plasma processing apparatus 10 may be configured to be capable of varying the inter-electrode distance between the shower head 30 and the stage 16. FIG. 11 is a diagram schematically illustrating an example of a cross section of a plasma processing apparatus according to another exemplary embodiment. A plasma processing apparatus 10 shown in FIG. 11 includes a substrate support 13 and a shower head 30. The substrate support 13 is disposed within the chamber 12 near a center thereof, and supports a wafer W. Though not shown, the substrate support 13 has the same configuration as that of FIG. 1, and a radio frequency power is applied to this substrate support 13 when plasma is formed. The shower head 30 is disposed to face the substrate support 13. The shower head 30 and the substrate support 13 serve as an upper electrode and a lower electrode, respectively. Furthermore, the plasma processing apparatus 10 is further equipped with an elevator 200 configured to move the shower head 30 up and down. The elevator 200 is configured to move the shower head 30 up and down between a ceiling of the chamber 12 and the substrate support 13. The shower head 30 is provided with a bellows 210 which surrounds the elevator 200. The bellows 210 is airtightly connected to a ceiling wall of the chamber 12 and a top surface of the shower head 30. The chamber 12 has therein a cylindrical wall 220 surrounding the shower head 30, a processing space 12c and the substrate support 13. An exhaust port 51 is provided at a bottom of a side portion of the chamber 12. The exhaust port 51 is connected with an exhaust device 50 via an exhaust line 52. The exhaust device 50 evacuates the chamber 12 through the exhaust port 51 and the exhaust line 52, thus allowing the inside of the chamber 12 to be decompressed to a required pressure level.

The chamber 12 is provided with a baffle plate 48 at an upstream of the exhaust port 51 with regard to a flow of an exhaust gas toward the exhaust port 51. The baffle plate 48 is disposed between an inner surface of a lower portion of the cylindrical wall 220 and the substrate support 13 to surround the substrate support 13. The chamber 12 is partitioned by the baffle plate 48 into a processing space 12c in which the wafer W is processed by using the plasma and an exhaust space connected with an exhaust system such as the exhaust line 52 and the exhaust device 50 configured to evacuate the chamber 12. The processing space 12c is a space formed by a bottom surface of the shower head 30, the cylindrical wall 220, the baffle plate 48 and the substrate support 13. The processing space 12c is a space formed by, for example, the bottom surface of the shower head 30, an inner surface of the cylindrical wall 220, the baffle plate 48 and the substrate support 13. The exhaust space is a space formed by, for example, an inner wall surface of the chamber 12, the corresponding surface cylindrical wall 220, an upper portion of a peripheral portion of the shower head 30, and the ceiling of the chamber 12.

Here, in cleaning using plasma, it is difficult to remove a by-product in a region within the chamber 12 which is not exposed to the plasma and radio frequency powers. Thus, a heater 55 is disposed in the region within the chamber 12 not exposed to the plasma and the radio frequency power. As an example, the heater 55 is disposed in the exhaust space. For example, the heater 55 is provided in a space 230 formed by an outer side of the cylindrical wall 220, the shower head 30, and the ceiling of the chamber 12. With this configuration, the plasma processing apparatus 10 is capable of suppressing deposition of the by-product in the space 230. Moreover, the plasma processing apparatus 10 is capable of suppressing a temperature of an outer surface of the chamber 12 corresponding to the space 230 to equal to or less than a tolerance temperature.

Further, though the above-described plasma processing apparatus 10 is the plasma processing apparatus configured to perform etching as the plasma processing, the exemplary embodiment may be applicable to various of other kinds of plasma processing apparatuses configured to perform a plasma processing. For example, the plasma processing apparatus 10 may be a single-wafer deposition apparatus configured to perform chemical vapor deposition (CVD), an atomic layer deposition (ALD), a physical vapor deposition (PVD), or the like, or may be a plasma processing apparatus configured to perform plasma annealing, plasma implantation, or the like.

Moreover, in the above-described exemplary embodiments, though the substrate is the semiconductor wafer, the substrate is not limited thereto. By way of example, the substrate may be any of various other kinds of substrates such as a glass substrate.

According to the exemplary embodiment, it is possible to suppress the by-product from being deposited in the region within the chamber which is not exposed to the plasma and the radio frequency power.

From the foregoing, it will be appreciated that various exemplary embodiments of the present disclosure have been described herein for the purposes of illustration, and that various modifications may be made without departing from the scope and spirit of the present disclosure. Accordingly, the various exemplary embodiments disclosed herein are not intended to be limiting, with the true scope and spirit being indicated by the following claims.

We claim:

1. A plasma processing apparatus, comprising:
a chamber configured to process a substrate by using a plasma;
a heater disposed in a region within the chamber which is not exposed to the plasma and a radio frequency power; and
a heater power supply configured to supply a pulsed power to the heater.

2. The plasma processing apparatus of claim 1, further comprising:
a substrate support configured to support the substrate;
an exhaust port through which a gas within the chamber is exhausted; and
a baffle plate disposed between an inner side surface of the chamber and the substrate support, and configured to partition the chamber into a processing space in which the substrate is processed and an exhaust space including the exhaust port,
wherein the heater is disposed in the exhaust space.

3. The plasma processing apparatus of claim 2,
wherein the heater is disposed to surround the substrate support.

4. The plasma processing apparatus of claim 1, further comprising:
a substrate support configured to support the substrate;
an upper electrode disposed to face the substrate support;
an elevator configured to move the upper electrode up and down between a ceiling of the chamber and the substrate support; and
a cylindrical wall provided within the chamber to surround the substrate support and the upper electrode,
wherein the heater is disposed in a space which is formed by an outer side of the cylindrical wall, the upper electrode and the ceiling of the chamber.

5. The plasma processing apparatus of claim 1,
wherein the heater is an infrared heater.

6. The plasma processing apparatus of claim 1, further comprising:
a controller configured to control the heater power supply to perform a processing comprising:
supplying the power to the heater until a temperature of the region not exposed to the plasma and the radio frequency power reaches a temperature at which a by-product attached to the region not exposed to the plasma and the radio frequency power is volatilized;
stopping the supplying of the power; and
repeating the supplying of the power and the stopping of the supplying of the power.

7. The plasma processing apparatus of claim 6,
wherein in the repeating of the supplying of the power and the stopping of the supplying of the power, the controller repeats the supplying of the power and the stopping of the supplying of the power such that a temperature of an outer surface of the chamber becomes equal to or lower than a tolerance temperature which is lower than the temperature at which the by-product is volatilized.

8. The plasma processing apparatus of claim 6,
wherein the controller includes processing the substrate by using the plasma while placing the substrate on a substrate support and cleaning an inside of the chamber without placing the substrate on the substrate support,
wherein the processing of the substrate by using the plasma comprises:
supplying the power to the heater until the region not exposed to the plasma and the radio frequency power reaches a first temperature;
stopping the supplying of the power; and
repeating the supplying of the power and the stopping of the supplying of the power, and
wherein the cleaning of the inside of the chamber comprises:
supplying the power to the heater until the region not exposed to the plasma and the radio frequency power reaches a second temperature;
stopping the supplying of the power; and
repeating the supplying of the power and the stopping of the supplying of the power.

9. The plasma processing apparatus of claim 8,
wherein the by-product is a titanium-based by-product,
the first temperature is in a range from 80° C. to 100° C., and
the second temperature is in a range from 100° C. to 120° C.

10. A plasma processing method, comprising:
processing a substrate by using a plasma within a chamber; and
supplying a pulsed power to a heater disposed in a region within the chamber which is not exposed to plasma and a radio frequency power.

11. The plasma processing apparatus of claim 1,
wherein a frequency of the pulsed power is equal to or lower than 0.05 Hz.

12. The plasma processing method of claim 10,
wherein a frequency of the pulsed power is equal to or lower than 0.05 Hz.

13. The plasma processing apparatus of claim 8,
wherein the first temperature is a temperature at which the by-product is suppressed from being attached, and the second temperature is a temperature at which removal of the by-product is accelerated.

14. The plasma processing apparatus of claim 6, further comprising:
a temperature sensor.
